(19) United States
(12) Patent Application Publication
(10) Pub. No.: US 2010/0302729 A1
(43) Pub. Date: Dec. 2, 2010

(54) HIGH POWER SOLID STATE POWER CONTROLLER PACKAGING

(76) Inventors: DON TEGART, Mississauga (CA); ZHENNING LIU, Mississauga (CA)

Correspondence Address: HONEYWELL/SHIMOKAJI;PATENT SERVICES, 101 Columbia Road, P.O.Box 2245, Morristown, NJ, 07962-2245, US

(21) Appl. No.: 12/472,596

(22) Filed: May 27, 2009

(51) Int. Cl. H05K 7/20; H05K 7/00

(52) U.S. Cl. 361/692; 361/698; 361/709; 361/729

(57) ABSTRACT

A high power solid state power controller packaging system and power panel are disclosed. The high power solid state power controller packaging system includes a plurality of discrete power devices assembled juxtaposed to one another in a row, a fin style heatsink, an input bus bar and an output bus bar, and a circuit card assembly connected to the plurality of discrete power devices for managing power signals among the plurality of discrete power devices. The power panel includes a chassis, a mounting bracket with connector sockets formed in the mounting bracket, and a plurality of high power solid state power control modules modularly mounted in the connector sockets.

### BACKGROUND OF THE INVENTION

The present invention generally relates to electronic component packaging and more particularly, to packaging for high power solid state controller devices.

Solid State Power Controller (SSPC) technology is gaining acceptance as a modern alternative to the combination of conventional electro-mechanical relays and circuit breakers for commercial aircraft power distribution due to its high reliability, “soft” switching characteristics, fast response time, and ability to facilitate advanced load management and other aircraft functions. Some solid state power controllers with a current rating less than 15 A are widely used in aircraft secondary distribution systems. However, power dissipation, voltage dropping, current sensing, and leakage current are attributes posing challenges in solid state power switching devices in applications with higher voltage and higher current ratings in aircraft primary distribution systems.

A typical SSPC mainly comprises a solid state switching device (SSSD), which performs the fundamental power on/off switching, and a SSPC processing engine, which is responsible for SSSD on/off control and feeder wire protection. It is usually housed in a form of line replaceable module (LRM—typically a conventional printed wiring board (PWB)) containing multiple SSPC channels.

In order to increase the current rating of an SSPC and to achieve reasonable low cost, significantly higher numbers of discrete power semiconductor devices, such as MOSFETs and potentially IGBTs in combination, may have to be used to form the SSSD, which drives the physical size and the demand for better thermal management. In addition, for higher current applications, using a conventional shunt resistor for current sensing is not suitable, and a current transformer or a Hall effect sensor may have to be used, which adds more complications to a compact SSPC design, and makes a multi-channel LRM solution for high power SSPC applications impractical.

As can be seen, there is a need to provide an effective packaging solution for the high power SSPCs to be used in the primary distribution system in order to facilitate the compact, modular, and scalable power distribution panel concept.

### SUMMARY OF THE INVENTION

In one aspect of the present invention, a high power solid state power controller packaging system, comprises a plurality of discrete power devices assembled juxtaposed to one another in a row; a fin style heatsink for transference of heat away from the discrete power devices, wherein the plurality of discrete power devices are mounted planar and onto the heatsink; an input bus bar and an output bus bar mounted within the packaging system in electrical connection with the plurality of discrete power devices; and a circuit card assembly connected to the plurality of discrete power devices for managing power signals among the plurality of discrete power devices.

In another aspect of the present invention, a high power solid state power control module, comprises a housing; a direct copper bond plate mounted in the housing; a plurality of power dies mounted onto a first side of the direct copper bond plate; an input bus bar and an output bus bar mounted in the housing in connection with and for transferring power into and away from the plurality of power dies; a circuit card assembly mounted in the housing spaced from the direct copper bond plate; a set of interconnect pins for providing an electrical connection to the plurality of power dies using wiring bonding; and a fin style heatsink mounted to a second side of the direct copper bond plate.

In another aspect, a high power solid state power control power panel, comprises a chassis; a mounting bracket mounted in the chassis; a plurality of connector sockets formed in the mounting bracket; and a plurality of high power solid state power control modules modularly mounted electrically and physically in parallel to one another on the mounting bracket, wherein the connector sockets are configured to modularly receive respective high power solid state power control modules.

These and other features, aspects and advantages of the present invention will become better understood with reference to the following drawings, description and claims.

### BRIEF DESCRIPTION OF THE DRAWINGS

FIG. 1A depicts a front perspective view of a high power solid state power controller packaging system in accordance with an exemplary embodiment of the present invention;

FIG. 1B depicts a rear perspective view of a high power solid state power controller packaging system in accordance with an exemplary embodiment of the present invention;

FIG. 1C depicts a front perspective view of a high power solid state power controller packaging system without a circuit card assembly in accordance with an exemplary embodiment of the present invention;

FIG. 1D depicts a side view of the high power solid state power controller packaging system shown in FIG. 1C;

FIG. 2A depicts a rear perspective view of a high power solid state power control module in accordance with another exemplary embodiment of the present invention;

FIG. 2B depicts a front perspective view of a high power solid state power control module in accordance with another exemplary embodiment of the present invention;

FIG. 2C depicts a front perspective view of interior of the high power solid state power control module shown in FIG. 2B;

FIG. 3A depicts a front perspective view of a high power solid state power control power panel in accordance with another exemplary embodiment of the present invention;

FIG. 3B depicts a front perspective view of the interior of the high power solid state power control power panel shown in FIG. 3A;

FIG. 3C depicts a rear perspective view of an internal component assembly in accordance with the exemplary embodiment of the present invention shown in FIG. 3A;

FIG. 3D depicts a front perspective view of an internal component assembly in accordance with the exemplary embodiment of the present invention shown in FIG. 3A;

FIG. 4A depicts a liquid cooled high power solid state power control module in accordance with another exemplary embodiment of the present invention; and

FIG. 4B depicts a liquid cooled high power solid state power control power panel in accordance with another exemplary embodiment of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Various inventive features are described below that can each be used independently of one another or in combination with other features.

Broadly, embodiments of the present invention generally provide packaging configurations for discrete high power devices. Exemplary embodiments include a packaging system for multiple discrete devices and a panel assembly for congregation of multiple packaging systems. Exemplary embodiments in accordance with the present invention provide compact, modular, and scalable packaging configurations and panel assemblies. A packaging system and panel assembly in accordance with the present invention may be used in high power applications such as power distribution systems in aircraft using power devices such as MOSFETS and IGBTs.

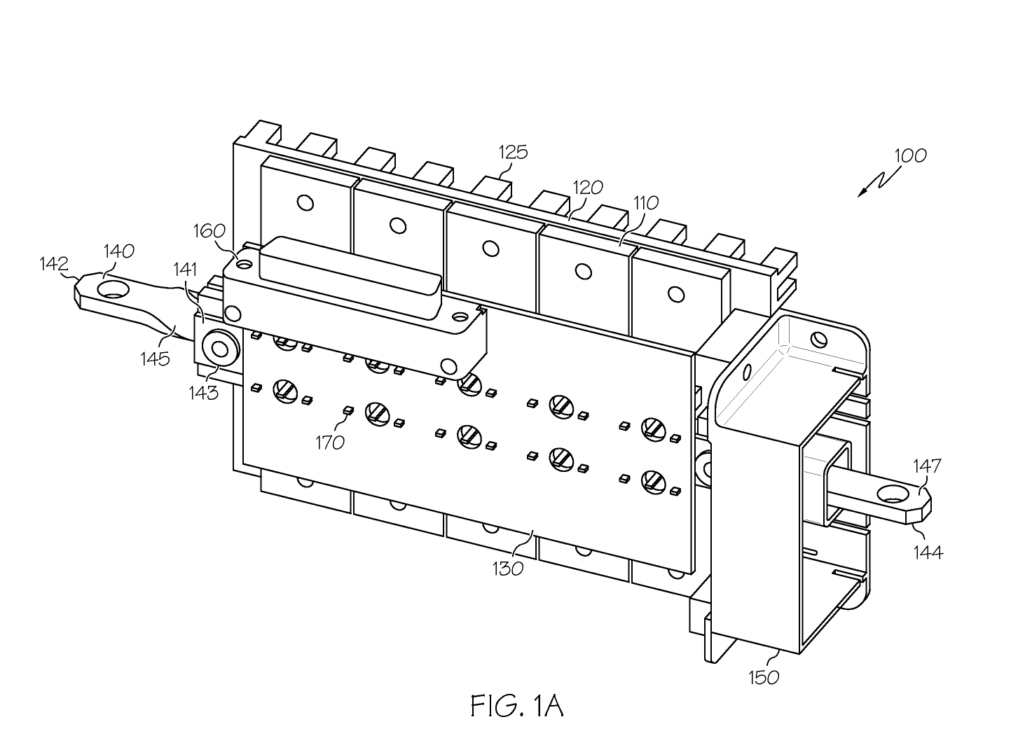

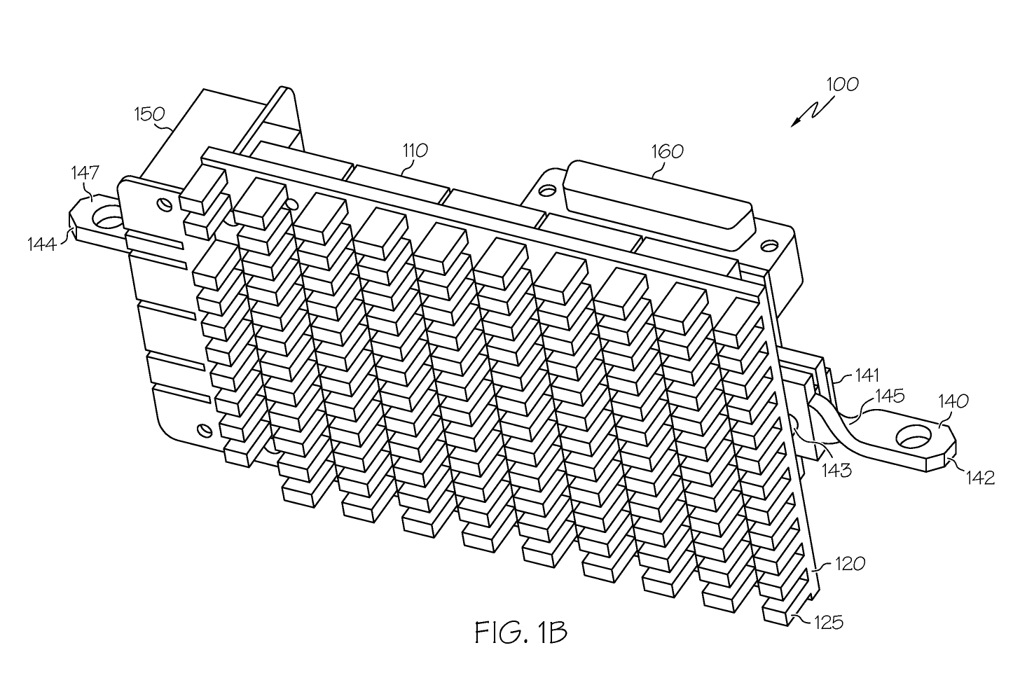

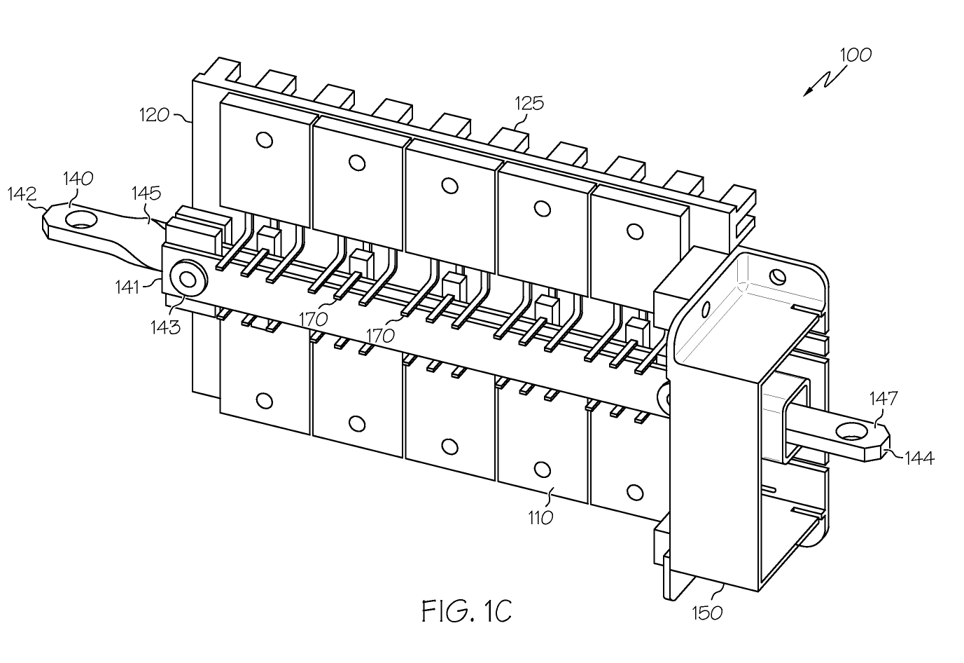

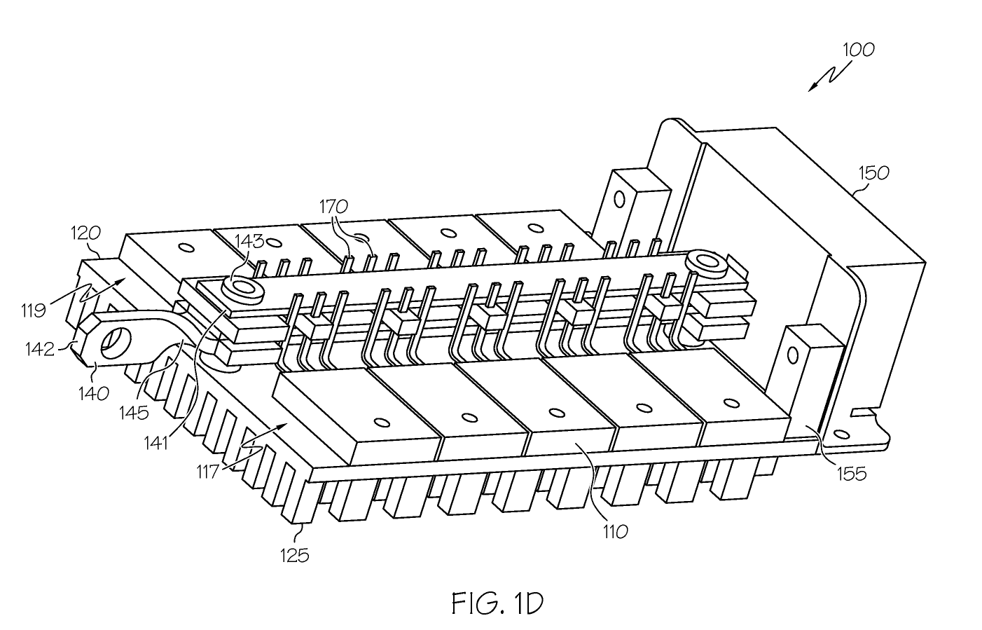

Referring to FIGS. 1A-1D, an exemplary embodiment of a high power solid state power controller packaging system 100 is shown. A plurality of discrete power devices 110 may be assembled juxtaposed to one another along two rows (117 and 119). The two rows (117;119) may be mounted spaced from one another with the edges of one row of discrete power devices 110 above the other row. The discrete power devices 110 may be mounted planar and onto a heat sink 120 for transference of heat generated by the discrete power devices away from the power devices. The heatsink 120 may comprise a plurality of fins 125. While a pin fin style heatsink is shown, it will be understood that different standard heatsink configurations such as folded fin or straight fin extrusions may be employed.

Referring specifically to FIGS. 1A, 1C, and 1D, an input bus bar 140 and an output bus bar 147 may traverse the length of the solid state power controller packaging system 100 atop the adjacent edges of the two rows of discrete power devices 110 and connected electrically to the discrete power devices 110 for the transmission of power into and out of the discrete power devices 110. The distal ends (142; 144) of the input bus bar 140 and the output bus bar 147 may project beyond the length of the heatsink 120. The input bus bar 140 may include a twist 145 allowing for the solid state power controller packaging system 100 to mount in a line-replaceable unit enclosure (not shown) in a manner similar to a card in a rack. This may allow for increased packaging density at the line-replaceable unit level where it allows for more of a three dimensional packaging of essentially two dimensional components. While only the input bus bar 140 is depicted with the twist 145, it will be understood that the output bus bar 147 may also include a twist 145 obstructed from view by a Hall effect current measuring device 150 mounted to the distal end of the output bus bar 147. The input bus bar 140 and output bus bar 147 may be isolated from the heat sink 120 by the use of nonconductive washers and spacers 143. Further isolation from the rest of the system 100 may be achieved by use of bus bar insulation 141 mounted on the outer side of respective bus bars 140, 147.

Each discrete power device 110 may include leads 170 formed such that they pass through the input bus bar 140 and output bus bar 147 and into a control circuit card assembly 130 where they are soldered into place. It will be understood that the leads 170 may represent gate-emitter-collector configurations as desired for a particular application. A control connector 160 may be mounted on the control circuit card assembly 130 connected to the aircraft level power control system (not shown) for managing power signals among the discrete power devices 110. Optionally, the Hall effect current measuring device 150 may be either mounted on the solid state power controller packaging system 100 or at the higher level line-replaceable unit assembly.

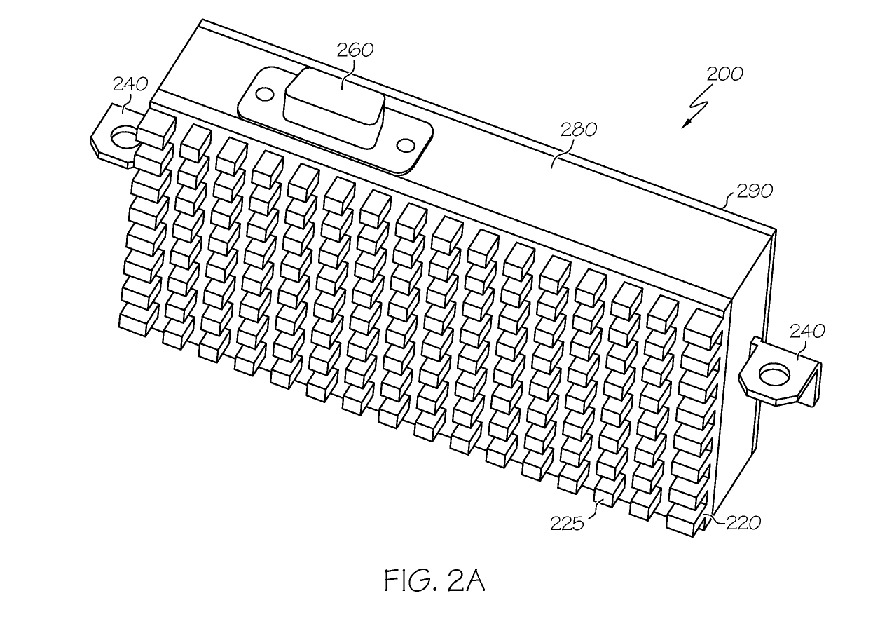

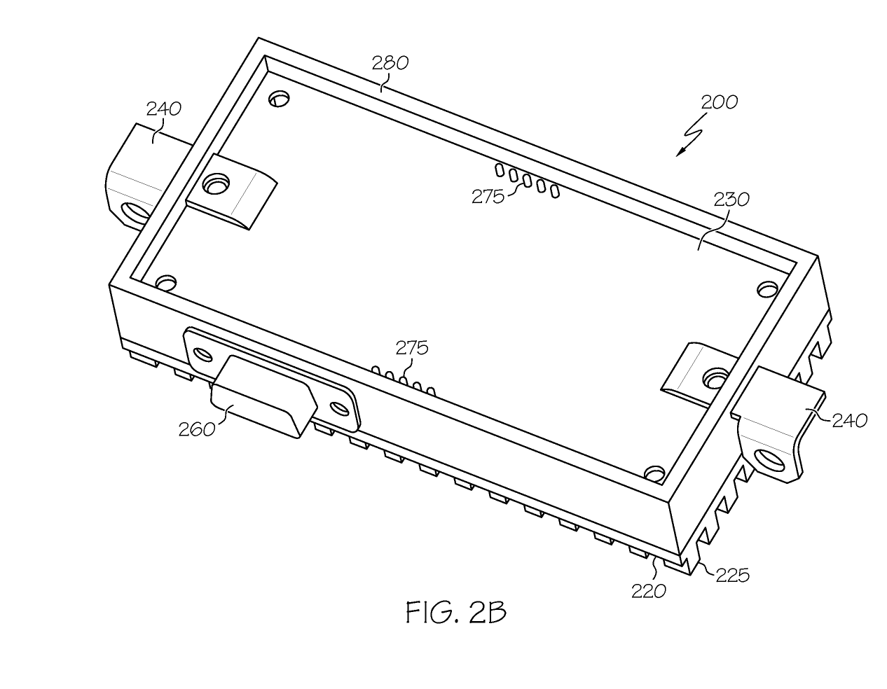

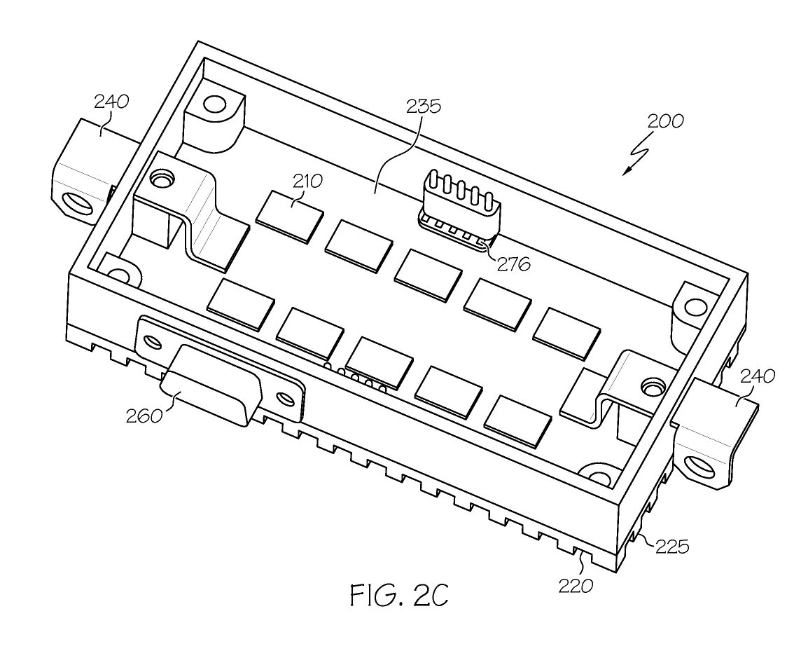

Referring to FIGS. 2A-2C, another exemplary embodiment in accordance with the present invention is shown. In order to reduce material and labor costs, weight and volume of component packaging, one exemplary embodiment may package power dies 210, into a single high power solid state power control module 200. A plastic housing 280 may house a plurality of power dies 210 mounted onto a direct copper bond plate 235 which in turn may be mounted to a metal heat sink 220 on the direct copper bond plate side opposite the plurality of power dies 210. The solid state power control module 200 may also include a cover 290 sealing closed the side opposite the heatsink 220. In one exemplary embodiment, a fin-style heatsink 220 employing an array of fins 225 is shown. It will be understood that other style heatsinks may be employed, however, a fin-style heatsink such as the one depicted, may provide improved heat transfer by permitting increased heatsink surface area to air contact and thus, desirable air cooling effectiveness.

Control signals may be routed into the high power solid state power control module 200 through a control/monitoring connector 260 connecting the power dies 210 to a line-replaceable unit level control system. The control/monitoring connector 260 may further route the control signals to a control circuit card assembly 230 mounted in the housing spaced from the direct copper bond plate 235. The circuit card assembly 230 may in turn route the signals through integrated housing pins 275. The power dies 210 may be mounted onto a direct copper bond plate 235 where signals may be sent through traces and other wiring (not shown) on the direct copper bond plate. For the sake of illustration, the power dies 210 are shown mounted within the high power solid state power control module 200 without wire bundles, wire bonds, and a dielectric gel but these elements will be understood as being employed. It will also be understood that wire bonds may be connected to respective power dies 210 from wire bond pads 276 that are in turn, connected to a set of interconnect pins 275 closing the signal path. Input/output bus bars 240 may be mounted to either end of the high power solid state power control module 200 and in direct contact with the direct copper bond plate 235 providing a pathway for power signals to traverse the package. In one exemplary embodiment, the input/output bus bars 240 may be formed rigid and bent to make contact with both the circuit card assembly and the direct copper bond plate. The input/output bus bars 240 may also be formed externally protruding from the ends of the high power solid state power control module 200 allowing the package to be solely mounted to higher level systems by the bus bars, as opposed to separate mounting supports.

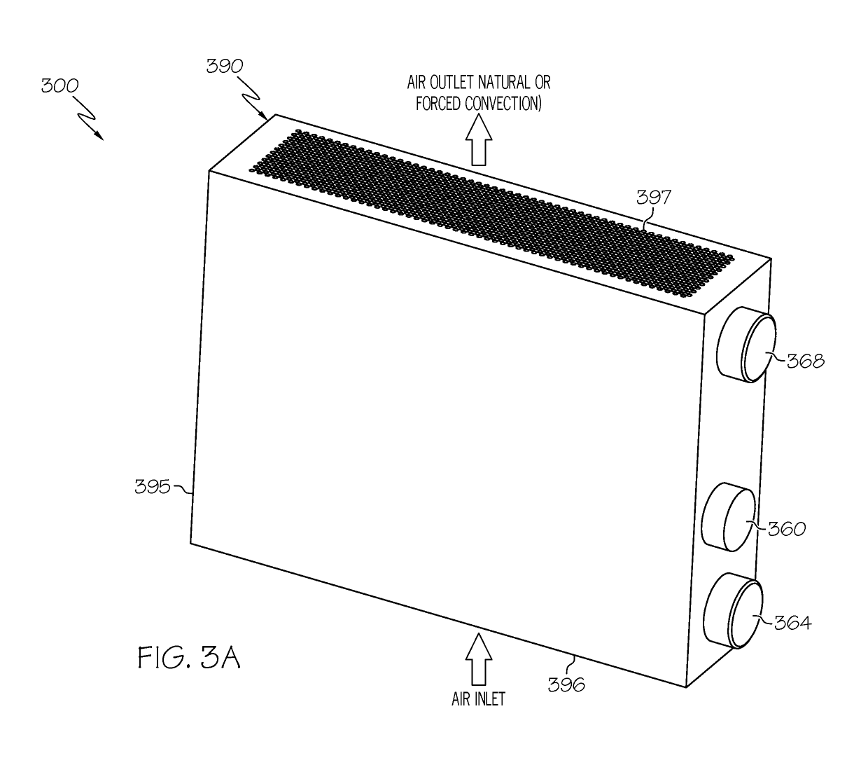

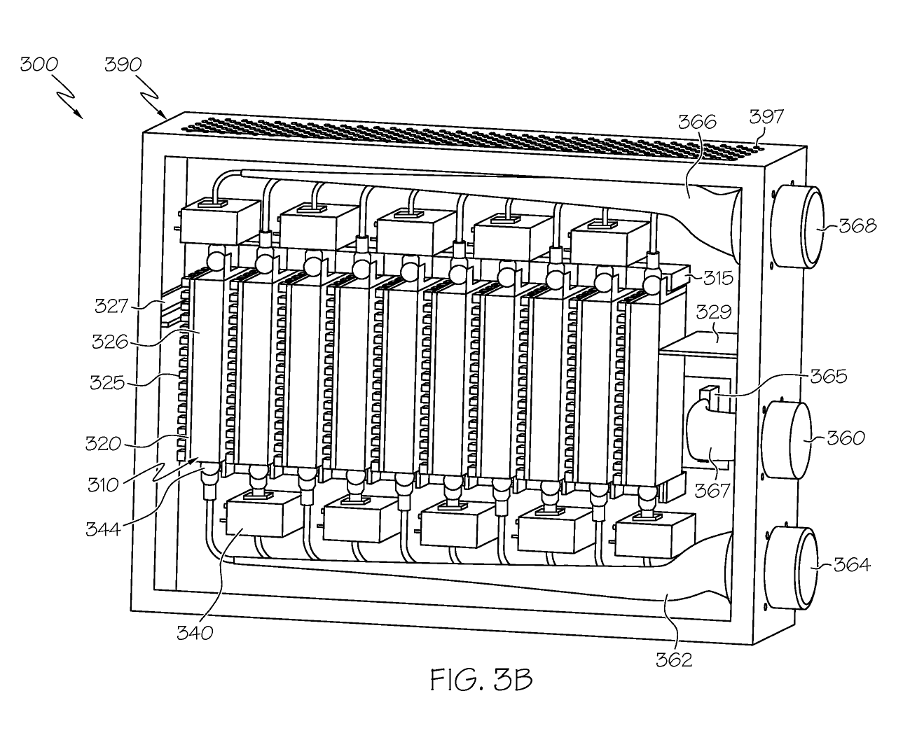

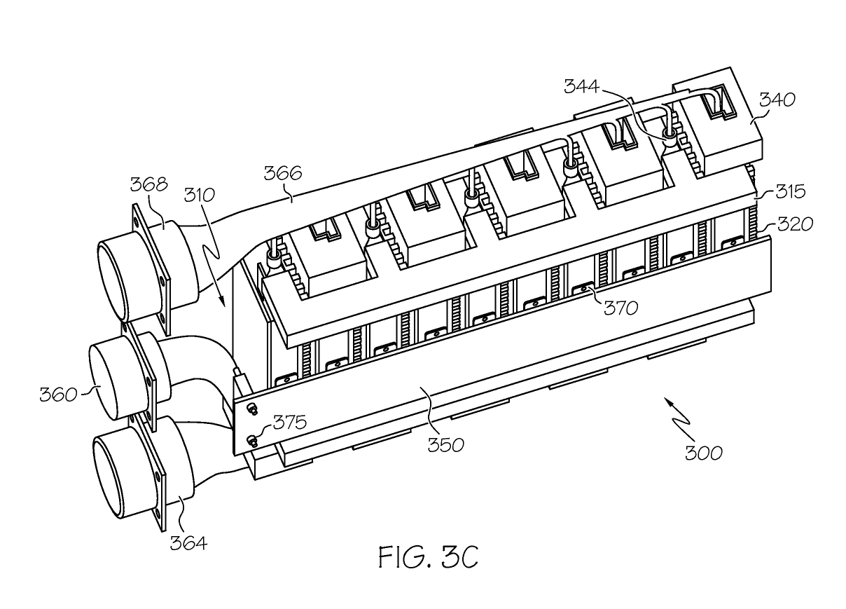

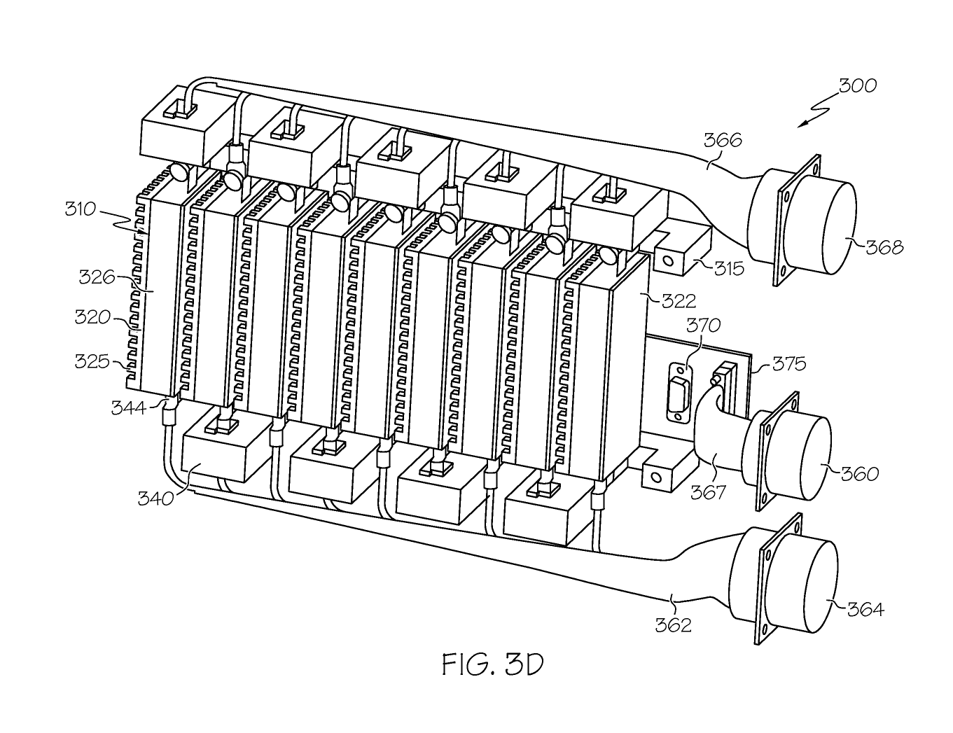

Referring now to FIGS. 3A-3D, an exemplary embodiment in accordance with the present invention can be assembled into a power panel 300. Referring specifically to FIGS. 3B and 3D, the power panel 300 may generally include a plurality of high power solid state power control modules 310 mounted in a modular capacity in parallel both electrically and physically to one another. The high power solid state power control modules 310 may be respectively housed within casings 326. The solid state power control modules 310 may be mounted onto a non-conductive mounting bracket (block) 375 that may also perform a secondary function of providing the bolted connection to a power wiring harness (seen in FIG. 3C). The mounting bracket 375 may include connector sockets 370 for plugging in individual solid state power control modules 310. The solid state power control modules 310 may include a heatsink 320 with fins 325 a casing 326, and a cover 322. While the internal components of the high power solid state power control modules 310 are not shown, it will be understood that they may include a power die configuration and electrical connection similar to the high power solid state control power module 200 described and shown in FIGS. 2A-2C.

Referring to FIGS. 3B, 3C, and 3D, input, output and control signals may be connected to the aircraft level wiring by aircraft harness connectors such as a control/monitoring connector 360, an input connector 364, and an output connector 368. An input power wire bundle 362 and an output power wire bundle 368 may route power into and out of the power panel 300 by wiring connected to each high power solid state power control module 310. The input/output power wiring for each high power solid state power control module 310 may be mounted by fasteners to mounting blocks 315. While the high power solid state power control modules 310 are shown with a screw type fastener and wiring system, it will be understood that other embodiments using higher powered solid state power control modules may instead use bus bars and terminal blocks instead of wires to pass the current. The wiring to each high power solid state power control modules 310 may be routed through a power measuring device 340 whose signal wires (not shown) would also be routed to an external signal connector. Exemplary power measuring devices may include current sensors such as Hall Effect sensors. When mounted into position, the high power solid state power control modules 310 may also have their control signals controlled by a motherboard circuit card assembly 350 that may route the control signals from the external control/monitor connector 360 via a control wire bundle 367 into a motherboard mating socket 365. This arrangement may allow for quick maintenance by allowing the remove all but two fasteners to replace a high power solid state power control modules 310.

Referring to FIG. 3A, the high power solid state power control modules (not shown) of the power panel 300 may be mounted in a line-replaceable unit chassis 390 with perforations to form an air inlet 396 and an air outlet 397 providing cooling by air flowing though the chassis. Walls 327 and 329 may be mounted within the chassis 390 to block heated air from bypassing the heatsinks 320 incorporating fins 325 thus, promoting a heat flow out of the air outlet 397. It will be understood that air cooling may be achieved depending on power dissipation by either natural convection or forced convection. For example, forced convection can be provided by fans integrated to the line-replaceable unit, positive pressure (blowing) supplied by the aircraft ECS system, or negative pressure (sucking) supplied by the aircraft ECS system. A removable cover 395 may enclose and seal the high power solid state power control modules within the chassis 390.

A control/monitoring connector 360, input connector 364, and output connector 368 may protrude from the chassis 390. While embodiments of the power panel 300 have been depicted with the control/monitoring connector 360, input connector 364, and output connector 368 on the same side of the chassis 390, it will be understood that the connectors may be mounted onto the chassis 390 as convenient for the mounting onto the line-replaceable unit system.

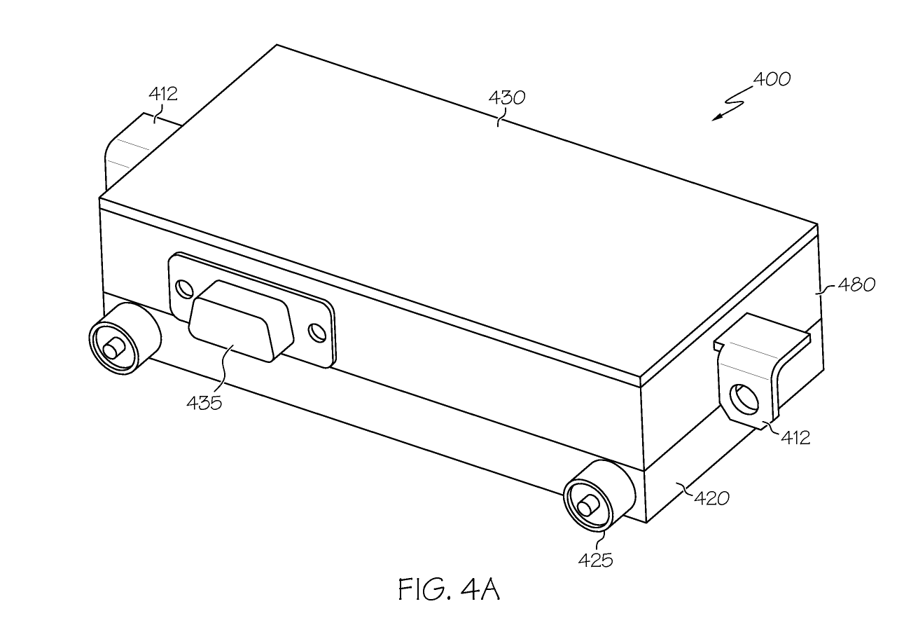

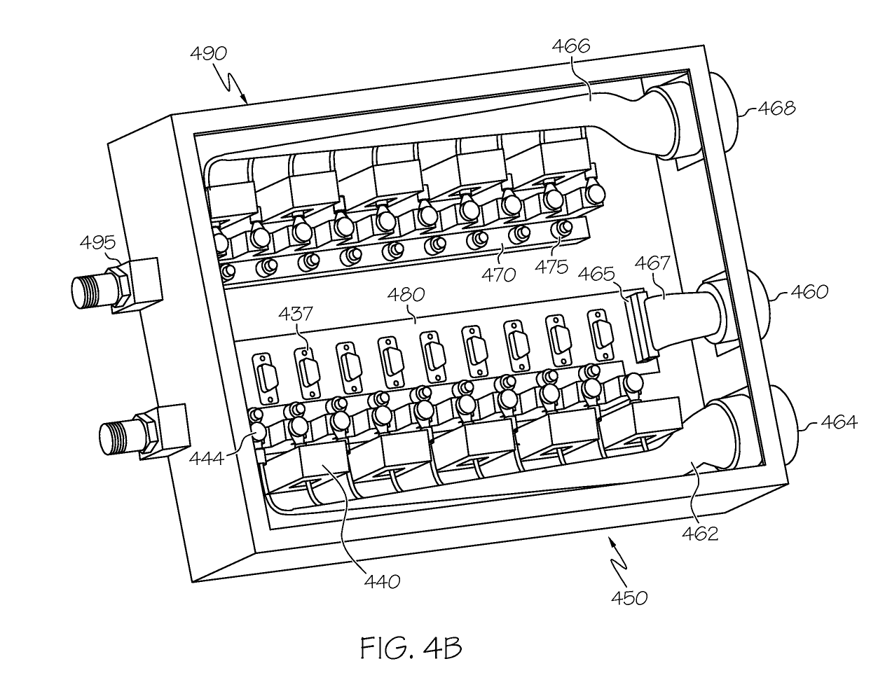

It may also be desirable for both commercial and military aircraft continue to move the electrical cooling provisions more towards a liquid based system as increased amounts of electrical equipment are being mounted on board. Referring to FIG. 4A, a high power solid state control power module 400 similar to the one described in FIGS. 2A-2C can be modified to use liquid cooling by replacing the air cooled integrated heat sink 220 for a liquid integrated heatsink 420 with fluid fittings 425. The high power solid state control power module 400 may further include a housing 480, a cover 430, bus bars 412, and a controller connector 435. A module in accordance with the exemplary embodiment of the high power solid state module 400 may provide for an extremely high power application version of a power panel 450.

Referring specifically to FIG. 4B, the power panel 450 may be similar to the power panel 300 of FIGS. 3A-3D except that the power panel 450 may include fluid manifolds 470 including fluid fittings 475 for the routing of the inlet and outlet fluids to the high power solid state control power module 400 (for sake of illustration, not shown connected within the power panel 450). The fluid fittings 475 may be configured to fit in connection with the fluid fittings 425 on the high power solid state control power module 400 and may be engaged by a bolting action of the high power solid state control power module 400 into place within the power panel 450 as in the same manner as the air cooled version (power panel 300). Additionally, externally mounted chassis fluid fittings 495 may be fluidly connected to the fluid manifolds 470 to provide a pathway for cooling fluid into the power panel 450. To enable the engagement of the fluid fittings (425; 475) without fluid loss and without retention mechanisms quick disconnect fittings may be used such as those available from Aeroquip (AE70840A and AE71569A) which are use in such applications as SEM-E format liquid cooled circuit card assemblies on military aircraft.

Electrical connections and control/monitoring signals may be achieved similar to the manner described in the power panel 300 shown in FIGS. 3A-3D by the employment of a control/monitoring connector 460 connected to a control wire bundle 467, an inlet connector 464 connected to an input power wire bundle 462, and an outlet connector 468 connected to an output power wire bundle 466. Input and output power may be fed into individual high power solid state control power modules 400 through power measuring devices 440 and secured by fasteners 444. Control signals may be transmitted from the control/monitor connector 460 to a motherboard 480 through a motherboard interface 465. The motherboard 480 may manage and transmit signals to individual high power solid state control power modules 400 through module connectors 437.

It should be understood, of course, that the foregoing relates to exemplary embodiments of the invention and that modifications may be made without departing from the spirit and scope of the invention as set forth in the following claims.

We claim:

1. A high power solid state power controller packaging system, comprising:
a plurality of discrete power devices assembled juxtaposed to one another in a row;
a fin style heatsink for transference of heat away from the discrete power devices, wherein the plurality of discrete power devices are mounted planar and onto the heatsink;
an input bus bar and an output bus bar mounted within the packaging system in electrical connection with the plurality of discrete power devices; and
a circuit card assembly connected to the plurality of discrete power devices for managing power signals among the plurality of discrete power devices.

2. The high power solid state power controller packaging system of claim 1, further comprising a control connector connected to the circuit card assembly receiving signals from an aircraft level power control system.

3. The high power solid state power controller packaging system of claim 1, further comprising a current measurement device connected to the output bus bar for measuring output current in the system.

4. The high power solid state power controller packaging system of claim 1, wherein the input bus bar includes a twist.

5. A high power solid state power control module, comprising:
a housing;
a direct copper bond plate mounted in the housing;
a plurality of power dies mounted onto a first side of the direct copper bond plate;
an input bus bar and an output bus bar mounted in the housing in connection with and for transferring power into and away from the plurality of power dies;
a circuit card assembly mounted in the housing spaced from the direct copper bond plate;
a set of interconnect pins for providing an electrical connection to the plurality of power dies using wiring bonding; and
a fin style heatsink mounted to a second side of the direct copper bond plate.

6. The high power solid state power control module of claim 5, further comprising a controller connector connected to the circuit card assembly for transmitting control signals to the power dies.

7. The high power solid state power control module of claim 5, wherein the input bus bar and output bus bar make contact with both the circuit card assembly and the direct copper bond plate.

8. The high power solid state power control module of claim 5, wherein the input bus bar and output bus bar protrude externally from ends of the module.

9. A high power solid state power control power panel, comprising:
a chassis;
a mounting bracket mounted in the chassis;
a plurality of connector sockets formed in the mounting bracket; and
a plurality of high power solid state power control modules modularly mounted electrically and physically in parallel to one another on the mounting bracket, wherein the connector sockets are configured to modularly receive respective high power solid state power control modules.

10. The high power solid state power control power panel of claim 9 further comprising a current measurement device connected to each respective high power solid state power control module.

11. The high power solid state power control power panel of claim 9 further comprising an air inlet on the chassis and an air outlet on the chassis configured to provide air flow in and out of the chassis.

12. The high power solid state power control power panel of claim 11, wherein the high power solid state power control modules each respectively include a heat sink configured to promote cooling airflow out of the air outlet.

13. The high power solid state power control power panel of claim 11, wherein the chassis includes walls configured to promote cooling airflow out of the air outlet.

14. The high power solid state power control power panel of claim 9, further comprising a control motherboard mounted onto the chassis for controlling signals in the high power solid state power control modules.

15. The high power solid state power control power panel of claim 9, further comprising:
an input wire bundle connected to respective high power solid state power control modules for providing power into each respective high power solid state power control module; and
an output wire bundle connected to respective high power solid state power control modules for transmitting power out from each respective high power solid state power control module.

16. The high power solid state power control power panel of claim 9, wherein the high power solid state power control module are liquid cooled.

17. The high power solid state power control power panel of claim 9, further comprising:
chassis fluid fittings mounted to the chassis;
a fluid manifold in fluid connection with the chassis fluid fittings; and
module fluid fittings mounted on the high power solid state power control modules in fluid connection with the fluid manifold.
